(19) United States
(12) Patent Application Publication
(10) Pub. No.: US 2009/0178764 A1
(43) Pub. Date: Jul. 16, 2009

(54) Plasma processing apparatus including electrostatic chuck with built-in heater

(75) Inventors: Seiichiro Kanno, Kodaira (JP); Tsunehiko Tsubone, Hikari (JP); Hiroho Kitada, Kudamatsu (JP)

Correspondence Address: MCDERMOTT WILL & EMERY LLP, 600 13TH STREET, N.W., WASHINGTON, DC, 20005-3096, US

(73) Assignee: HITACHI HIGH-TECHNOLOGIES CORPORATION

(21) Appl. No.: 12/073,082

(22) Filed: Feb. 29, 2008

(30) Foreign Application Priority Data
Jan. 11, 2008 (JP) 2008-004414

(51) Int. Cl. H01L 21/3065

(52) U.S. Cl. 156/345.52

(57) ABSTRACT

A plasma processing apparatus is provided that includes a heater-built-in electrostatic chuck, prevents a direct-current potential difference from being made in the plane of a wafer during plasma processing, and performs plasma processing while controlling the temperature of the wafer with good responsiveness without damaging a semiconductor device. The heater-built-in electrostatic chuck of the plasma processing apparatus has a structure in which an insulator, two heaters, an insulator, two electrostatic chuck electrodes having approximately identical areas, and a dielectric film are laminated in ascending order on a conductive base material to which a bias voltage is to be applied. The heaters have approximately identical areas, and are disposed below the two electrostatic chuck electrodes, respectively. Power is provided to the heaters via a low-path filter and a coaxial cable.

### CLAIM OF PRIORITY

The present application claims priority from Japanese application JP 2008-4414 filed on Jan. 11, 2008, the content of which is hereby incorporated by reference into this application.

### FIELD OF THE INVENTION

The present invention relates to a plasma processing apparatus for processing a semiconductor wafer. In particular, the invention relates to a plasma processing apparatus that processes a semiconductor wafer while holding it with a heater-built-in electrostatic chuck.

### BACKGROUND OF THE INVENTION

Circuit patterns to be processed into semiconductor wafers have increasingly been made finer as the packing density of semiconductor elements is increased. Accordingly, more stringent processing dimensional accuracies have been required. Under these circumstances, it is extremely important to temperature-control a wafer (semiconductor wafer) being processed.

For example, if a wafer is etched using plasma, a high-frequency voltage is normally applied to the wafer so as to generate a bias voltage on the wafer. By accelerating ions using an electric field generated in this way to draw the ions into the wafer, a desired anisotropic shape is realized. At this time, the wafer is subjected to heat input; therefore its temperature is increased.

Such an increase in wafer temperature affects an etching result. For example, if polysilicon that will serve as an electrode of a semiconductor device is etched, a line width to be ultimately obtained is significantly affected by deposition of reaction products attached onto a sidewall of the polysilicon during the etching. The deposition rate of the reaction products varies with the wafer temperature. Therefore, a failure to temperature-control the wafer being processed brings an etching result with poor reproducibility. Also, the density distribution of reaction products tends to be lower around the periphery of the wafer than around the center thereof. For this reason, the temperature distribution of the wafer must actively be managed to obtain uniform line widths (critical dimensions (CD)) in the plane of the wafer.

The density distribution and deposition rate of reaction products also vary with the material of a film to be processed or etching conditions. Accordingly, if the film material or etching conditions varies when one process is being performed as is the case with when an antireflective film and polysilicon are continuously processed, the optimum temperature distribution also varies.

Thus, in order to actively manage the temperature distribution of a wafer being processed using plasma, an electrostatic chuck has been proposed that includes a heater and increases or decreases the temperature of a wafer with good responsiveness by controlling power supplied to this heater (for example, see Japanese Patent Application Laid-Open (JP-A) No. 2004-71647).

Also, a working English title “Charging Damage in a Semiconductor Process,” Realize Science & Engineering Center Co., Ltd., pp. 297 discloses a relation between a voltage applied to a gate oxide film of a transistor and a leak current. Specifically, it discloses that if an electric field with intensity of 8M V/cm or higher has an effect on a gate oxide film, a leak current is rapidly increased, that is, the gate oxide film is broken down.

While JP-A No. 2004-71647 discloses a structure of a heater-built-in electrostatic chuck, it does not sufficiently take into consideration a method for feeding the electrostatic chuck and the like that should be noted if such an electrostatic chuck is applied to an actual plasma etching apparatus. For example, no consideration is given to a measure against a problem that may newly occur if such a heater-built-in electrostatic chuck is applied to a plasma processing apparatus, that is, a damage problem.

For example, if plural heaters are disposed below electrostatic chuck electrodes of a bipolar electrostatic chuck, the heaters do not always have identical areas, since the pattern of each heater must be adjusted to obtain a desired temperature distribution. If the heaters do not have identical areas, the capacitances of the heaters are not equal to the capacitance of the electrostatic electrodes. According to the inventors' study, if a high-frequency voltage is applied to a base material under such conditions, the high-frequency voltage applied to the heaters is leaked into a ground via the capacitance of a coaxial cable coupled to a heater power supply. Further, since the capacitances of the heaters are different from that of the electrostatic chuck electrodes, there is also a difference in degree of the leakage between the inner heater and outer heater. As a result, a difference is made between voltages generated on a surface of the electrostatic chuck. Although such a voltage difference made on the surfaces of the electrodes is reduced by a silicon wafer, a potential difference is also made on a surface of the wafer. At that time, a voltage is applied to a gate electrode of a transistor formed on the wafer. If such a voltage is equal to or higher than a withstand voltage, a semiconductor device on the wafer will be damaged.

### SUMMARY OF THE INVENTION

An advantage of the present invention is to provide a plasma processing apparatus that includes a heater-built-in electrostatic chuck and performs plasma processing while controlling the temperature of a wafer with good responsiveness so that no damage is caused to a semiconductor device.

A typical aspect of the present invention will be described below. That is, a plasma processing apparatus according to an aspect of the present invention includes: a sample stage provided in a processing chamber and intended to hold a sample; a plasma generating unit for generating plasma in the processing chamber; an electrostatic chuck electrode and a heater both disposed on the sample stage; a bias power supply coupled to the sample stage and intended to control ion energy; an exhaust device for decompressing the processing chamber; and a power restraint unit for preventing high-frequency power from flowing into the current-carrying path of the heater. The heater is coupled to a heater power supply via a current-carrying path.

According to the aspect of the invention, plasma processing is performed while controlling the temperature of a wafer with good responsiveness so that no damage is caused to a semiconductor device. As a result, a plasma processing apparatus is provided that allows a reduction in manufacturing cost of a semiconductor device as well as has high productivity.

### BRIEF DESCRIPTION OF THE DRAWINGS

Embodiments of the present invention will be described in detail with reference to the accompanying drawings, wherein:

FIG. 1 is a schematic sectional view of a heater-built-in electrostatic chuck according to a first embodiment of the present invention;

FIG. 2A is a drawing showing a heat pattern according to the first embodiment;

FIG. 2B is a drawing showing an electrostatic chuck electrode pattern according to the first embodiment;

FIG. 3 is a schematic sectional view of an effective magnetic field microwave plasma processing apparatus according to the first embodiment;

FIG. 4 is a diagram of an equivalent circuit model showing a basic concept of the present invention;

FIG. 5A is a diagram of an equivalent circuit model including a heater-built-in electrostatic chuck mechanism for showing an operation and an advantage of the first embodiment during etching;

FIG. 5B is a diagram showing states of high-frequency voltages applied to devices A and B in the first embodiment during the etching;

FIG. 6 is a schematic sectional view of a heater-built-in electrostatic chuck according to a third embodiment of the present invention;

FIG. 7 is a schematic sectional view of a heater-built-in electrostatic chuck according to a fourth embodiment of the present invention;

FIG. 8A is a diagram of an equivalent circuit model including a heater-built-in electrostatic chuck mechanism for showing an operation and an advantage of the fourth embodiment during etching;

FIG. 8B is a diagram showing states of high-frequency voltages applied to devices A and B in the fourth embodiment during the etching;

FIG. 9 is a schematic sectional view of a heater-built-in electrostatic chuck according to a fifth embodiment of the present invention;

FIG. 10A is a diagram of a heat pattern according the fifth embodiment;

FIG. 10B is a schematic sectional view of an effective magnetic field microwave plasma processing apparatus according to the fifth embodiment;

FIG. 11A is a diagram of an equivalent circuit model including a heater-built-in electrostatic chuck mechanism for showing an operation and an advantage of the fifth embodiment during etching;

FIG. 11B is a diagram showing states of high-frequency voltages applied to devices A and B in the fifth embodiment during the etching;

FIG. 12 is a graph showing a relation between a heater cable length and a potential difference made on a wafer in a case where a bias frequency is 400 KHz in the fifth embodiment;

FIG. 13 is a graph showing a relation between a heater cable length and a potential difference made on a wafer in a case where a bias frequency is 800 KHz in the fifth embodiment;

FIG. 14 is a graph showing a relation between a heater cable length and a potential difference made on a wafer in a case where a bias frequency is 2 MHz in the fifth embodiment;

FIG. 15 is a graph showing a relation between a heater cable length and a potential difference made on a wafer in a case where a bias frequency is 13.56 MHz in the fifth embodiment;

FIG. 16A is a drawing showing a map of occurrence of damages estimated using a damage TEG in a related art example;

FIG. 16B is a drawing showing a map of occurrence of damages estimated using a damage TEG in the fifth embodiment;

FIG. 17A is a diagram of a simplified equivalent circuit model for showing an occurrence mechanism of a damage that may occur in a heater-built-in electrostatic chuck; and

FIG. 17B is a diagram showing states of high-frequency voltages applied to devices A and B during etching in the equivalent circuit model of FIG. 17A.

### DETAILED DESCRIPTION OF THE PREFERRED EMBODIMENTS

The inventors newly found that if a wafer is processed while applying a bias voltage to an electrostatic chuck, a high-frequency voltage is leaked via a feeding cable for supplying power to a heater and thus a direct-current voltage difference may be made on the wafer and a current may pass through a gate insulating film formed in a semiconductor device on the wafer, thereby causing a damage to the device.

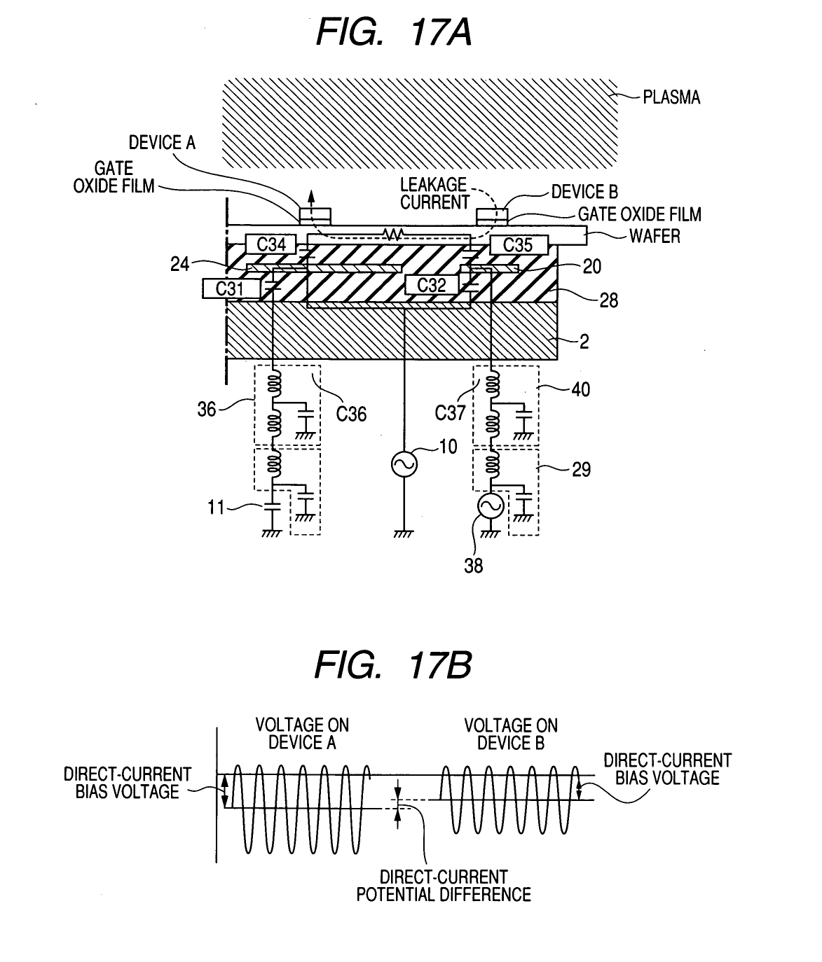

An occurrence mechanism of such damage will now be described with reference to FIGS. 17A and 17B. In order to plainly describe the mechanism, FIG. 17A shows a structure in which heaters and electrostatic chuck electrodes are disposed at a identical height. This structure is different from the structures of embodiments of the present invention to be described later, in each of which an electrostatic chuck is disposed above a heater. However, these structures have the same basic mechanism. Note that in FIG. 17A, an equivalent circuit model of a capacitance, a coil component, and a resistance existing between each of a current power supply, a frequency power supply, and a heater power supply, and a wafer is shown in an overlapping manner. A device A in FIG. 17A is an element formed on the wafer located above an electrostatic chuck internal electrode, and a device B is an element formed on the wafer located above the heater. FIG. 17B is a diagram showing states of the respective high-frequency voltages applied to the devices A and B during etching in the equivalent circuit model shown in FIG. 17A.

For the device A, high-frequency power applied to a base material for bias voltage application is applied onto the wafer via a capacitance C31 between the base material and electrostatic chuck internal electrode and a capacitance C34 between the electrostatic chuck internal electrode and wafer. For the device B, such high-frequency power is applied onto the wafer via a capacitance C32 between the base material and heater and a capacitance C35 between the heater and wafer. In this case, a part of the high-frequency power applied to the electrostatic chuck internal electrode is leaked via a stray capacitance C36 of a cable coupled to the direct current power supply. Also, a part of the high-frequency power applied to the heater is leaked via a stray capacitance C37 of a cable coupled to the heater power supply. Further, a part of electromagnetic waves to be provided and applied into a vacuum processing chamber to generate plasma, that is, a part of high-frequency power as plasma generation means such as microwave, ultrahigh frequency (UHF), or radio frequency (RF) is also leaked via the stray capacitance 37 of the cable coupled to the heater power supply.

If high-frequency power applied to the base material is applied to the wafer, the voltage drops from the original voltage applied to the base material. If the state of the coupling of the capacitances from the base material to the wafer and/or the state of the leakage from the cables from each of the electrostatic chuck internal electrode and heater to the power supply vary, a difference is made between the respective high-frequency applied to the devices A and B. As a result, a difference is made between the respective direct-current bias voltages generated on the devices A and B.

As a result, in the case of FIG. 17A, a leakage current from the device B toward the device A occurs. This causes dielectric deterioration of gate oxide films formed on the elements, that is, this causes damage to the gate oxide films. Such a damage caused by the heater-built-in electrostatic chuck, which was newly found by the inventors, is different in mechanism from a damage caused by a direct-current potential difference made on a wafer due to unevenness in a plasma distribution on the wafer, which is a damage that has been pointed out. For this reason, a new configuration for preventing this newly found damage must be considered.

Since the occurrence mechanism of such a damage has been clarified, it is understood that, in order to prevent this damage, the equivalent electric circuit from the base material to the device A and that from the base material to the device B are preferably made identical to each other or similar to each other to the extent that no damage is caused.

The present invention provides a plasma processing apparatus that includes a heater-built-in electrostatic chuck and performs plasma processing while controlling the temperature of a wafer with good responsiveness so that a direct-current potential difference is prevented from being made in the plane of the wafer undergoing plasma processing and thus no damage is caused to a semiconductor device.

In order to prevent a damage to a semiconductor device, a heater-built-in electrostatic chuck of a plasma processing apparatus is configured so that an insulator, at least two heaters, an insulator, two electrostatic chuck electrodes having approximately identical areas, and a dielectric film are laminated in ascending order on a conductive base material to which high-frequency power is to be applied for bias or plasma generation and so that the two heaters are disposed so that they are completely hidden behind the corresponding chuck electrodes when seen from the wafer.

Alternatively, a heater-built-in electrostatic chuck of a plasma processing apparatus is configured so that an insulator, two heaters, an insulator, two electrostatic chuck electrodes having approximately identical areas, and a dielectric film are laminated in ascending order on a conductive base material to which high-frequency-power is to be applied and so that the two heaters have approximately identical areas and the heaters are disposed below the two electrostatic chuck electrodes and fed via a low-path filter and a coaxial cable.

Alternatively, if an electrostatic chuck includes at least two heaters, it is configured so that an insulator, the at least two heaters, an insulator, two electrostatic chuck electrodes having approximately identical areas, and a dielectric film are laminated in ascending order on a conductive base material to which high-frequency power is to be applied and so that the heaters are fed via a low-path filter and a coaxial cable and at least one of the plural heaters is coupled to a ground via a variable capacitor.

Alternatively, a heater-built-in electrostatic chuck of a plasma processing apparatus is configured so that an insulator, at least two heaters, an insulator, a unipolar electrostatic chuck electrode, and a dielectric film are laminated in ascending order on a conductive base material to which high-frequency power is to be applied for bias or plasma generation and so that the heaters are disposed in a manner that they are completely hidden behind the unipolar chuck electrode when seen the wafer.

Alternatively, if an electrostatic chuck includes at least two heaters, it is configured so that an insulator, the at least two heaters, an insulator, two electrostatic chuck electrodes having approximately identical areas, and a dielectric film are laminated in ascending order on a conductive base material to which high-frequency power is to be applied and so that the heaters are fed via a low-path filter and a coaxial cable with a capacitance of approximately 100 pF/m or less and the distance between each of the heaters and the low-path filter is optimized according to a bias frequency.

Embodiments of the present invention will now be described in detail with reference to the accompanying drawings.

### First Embodiment

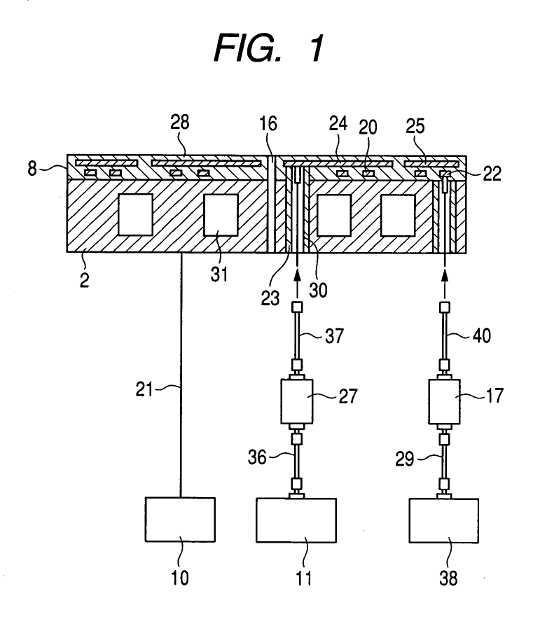

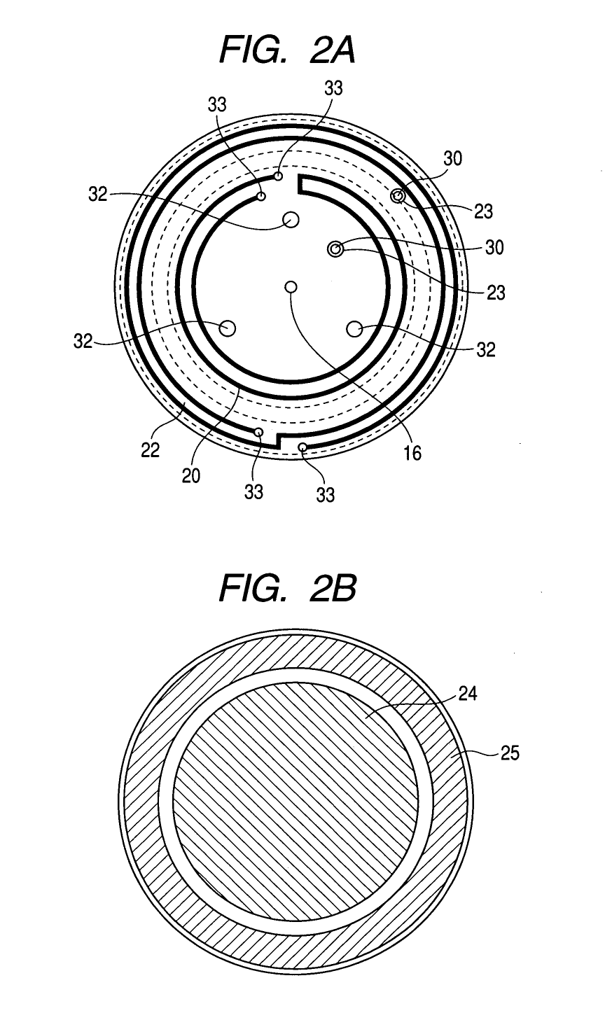

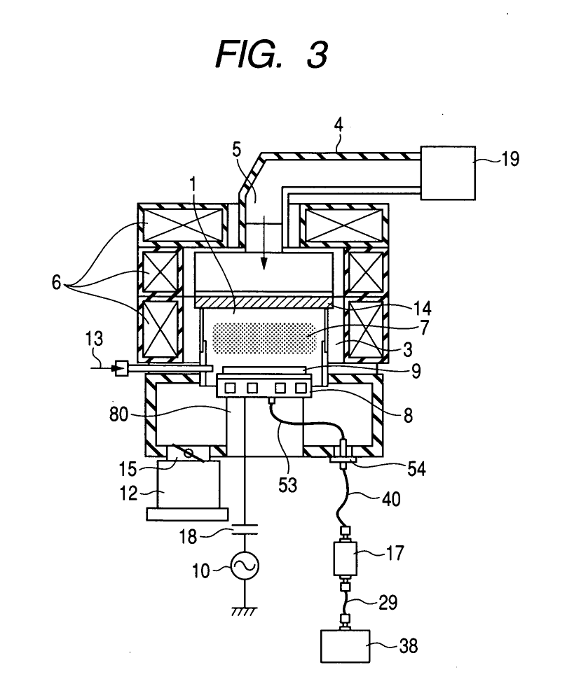

An electron-cyclotron-resonance (ECR) plasma processing apparatus according to a first embodiment of the present invention will be described with reference to FIGS. 1 to 5. FIG. 1 is a schematic sectional view of a so-called “bipolar electrostatic chuck” according to this embodiment. FIG. 2A is a drawing showing an example of a heat pattern according to this embodiment. FIG. 2B is a drawing showing an example of an electrostatic chuck pattern according to this embodiment. FIG. 3 is a schematic sectional view of the effective magnetic field microwave plasma processing apparatus according to this embodiment.

In the plasma processing apparatus including the bipolar electrostatic chuck according to the first embodiment, two heaters having approximately identical areas are disposed below two chuck electrodes having approximately identical areas so that they are completely hidden behind the corresponding chuck electrodes. Thus, a potential difference is prevented from being made between the devices A and B on the wafer placed above the respective electrostatic chuck electrodes.

As shown in FIG. 1, a sample stage of the plasma processing apparatus according to this embodiment includes a bipolar electrostatic chuck 8 with built-in heaters. Specifically, a multilayer structure is formed in which an insulator (dielectric film) 28, two heaters 20 and 22, an insulator (dielectric film) 28, two electrostatic chuck electrodes (inner electrostatic chuck electrode 24 and outer electrostatic chuck electrode 25) having approximately identical areas, and a dielectric film 28 are laminated in ascending order on a conductive base material 2. As shown in FIGS. 2B, the inner electrostatic chuck electrode 24 and outer electrostatic chuck electrode 25 have substantially identical areas. Disposed below these electrostatic chuck electrodes are two heaters, an inner heater 20 and an outer heater 22, having substantially identical areas. In FIG. 1, a reference numeral 10 represents a high-frequency power supply coupled to the conductive base material 2, and a reference numeral 11 represents a direct-current power supply 11 coupled to the two electrostatic chuck electrodes 24 and 25 via a filter 27 and coaxial cables 36 and 37. A reference numeral 38 represents a heater power supply coupled to the inner heater 20 and outer heater 22 via filters 17 and 40. The filters 17 and 27 are disposed outside a vacuum processing chamber 1. A reference numeral 30 represents a feeding through hole, a reference numeral 31 represents a coolant groove, and a reference numeral 33 represents a connection part of a feeding terminal of the heaters.

A configuration and an operation of the effective magnetic microwave plasma processing apparatus according to this embodiment will now be described with reference to FIG. 3. A wafer 9 to be processed is fixed using the electrostatic chuck 8 provided on the sample stage 80 in the vacuum processing chamber 1. A quartz window 14 is provided in an upper portion of the vacuum chamber 3, and a microwave 5 generated in a microwave oscillator 19 is introduced into the vacuum processing chamber 1 through a waveguide 4. A processing gas 13 introduced into the vacuum processing chamber 1 is put in a state of plasma 7 due to an interaction between the microwave 5 and a magnetic field generated by coils 6 attached to the periphery of the vacuum chamber 3. The wafer is processed (etched) is by being exposed to this plasma. The high-frequency power supply 10 that is coupled to the conductive base material 2 via the capacitor 18 and intended to control ion-energy controls the etching state by controlling entry of ions into the base material 2. The frequency of the high-frequency power supply 10 is, for example, 400 KHz.

A vacuum pump 12 maintains a pressure in a processing chamber 1 at a constant level by adjusting the opening of a valve 15. In this embodiment, the electrostatic chuck includes the heaters (inner heater 20 and outer heater 22), which are fed by the heater power supply 38.

The heater power supply 38 is coupled to a BNC type current introduction terminal 54 attached to the vacuum chamber via the filter 17 and the coaxial cables 29 and 40. The filter 17 is intended to prevent application of a high-frequency voltage of 400 KHz applied to the electrostatic chuck by the microwave and bias power supply, to the heater power supply. The back of the electrostatic chuck 8 and the terminal 54 of the current introduction terminal inside the vacuum chamber are coupled via a coaxial cable 53.

A structure and a manufacturing method of the electrostatic chuck according to this embodiment will now be described. First, a titanous base material 2 in which a coolant groove 31 for circulating a coolant is formed is prepared. Provided around the center of this base material are a helium through hole 16 for introducing a helium gas that ultimately becomes a cooling gas on the back of the wafer, and a feeding through hole 30 for feeding heater electrodes and electrostatic chuck electrodes. A ceramics pipe 23 for electric insulation is inserted into these through holes and fixed to the base material using an epoxy or silicon adhesive. Also, as shown in FIG. 2A, three carrier pusher-pin through holes 32 for attaching/detaching the wafer to/from the wafer are provided.

Next, in order to electrically insulate the heaters from the base material, high-resistance alumina 39 is uniformly thermal-sprayed onto the base material 2, and then a surface of the formed insulating layer is polished so that its thickness is adjusted. The thickness of the insulating layer depends on the withstand voltage of the high-resistance alumina and the manufacturing stability during thermal-spraying. Therefore, it is preferable to reduce the thickness as much as possible so as not to deteriorate the thermal characteristic while securing a withstand voltage higher than a voltage that may be applied between the base material and the heaters. While a voltage applied to the heaters is as low as the order of 100 V in any case of a direct current or an alternating current, a withstand voltage of 1 KV or higher is secured with respect to a thickness of 100 μm even if the temperature is 200° C., which is the highest possible temperature realized according to this embodiment. However, if a film is formed by thermal-spraying and then polished, the thickness of a film that can be formed stably is 100 to 150 μm. For this reason, the film thickness is set to 150 μm in this embodiment.

Next, tungsten is thermal-sprayed to form two heaters, the inner heater 20 and the outer heater 22. Unevenness in thickness of the heaters causes unevenness in calorific value; therefore, surfaces of the heaters are polished to adjust the thicknesses thereof. As with the insulating layer, the thicknesses of the heaters are also preferably on the order of 100 to 200 μm in terms of the manufacturing stability of thermal-sprayed films. For this reason, the thicknesses are set to 150 μm in this embodiment. One example of patterns of the two heaters is shown in FIG. 2A. The inner heater has three turns and the outer heater has two turns. A connection part 33 of a feeding terminal of each heater is coupled to an electric plug 34 buried in a ceramics pipe.

Next, the high-resistance alumina 35 is thermal-sprayed onto the heaters in order to insulate the heaters from electrostatic chuck electrodes, and a surface of the formed insulating layer is polished to adjust the thickness thereof. The thickness of the insulating layer depends on the withstand voltage of the high-resistance alumina. Therefore, the thickness must beta thickness such that the thermal characteristic is not deteriorated while securing a withstand voltage higher than voltage that may be applied to between the base material and heaters. While a voltage applied to the heaters is as low as the order of 100 V in any case of a direct current or an alternating current, the voltage of the electrostatic chuck may be applied to the heaters if any electrostatic electrode is broken (to be described later). Therefore, the thickness must be a thickness that withstands this voltage. The voltage applied to the electrostatic chuck electrodes depends on the resistance of the dielectric film (to be described later) that causes absorptive power. For a Coulomb type voltage that is relatively high, the voltage is conceivably 3 KV at the maximum. The withstand voltage of alumina also depends on the temperature. The inventors actually examined the withstand voltage at a temperature of 200° C. that is the substantially highest possible temperature realized by this embodiment. The withstand voltage was 750 V at the minimum per 100 μm. Also, it was 2 KV per 100 μm at a room temperature. Therefore, the insulating layer must have a thickness of 200 μm at a voltage of ±1.5 KV that is used in so-called “Johnsen-Rahbek type” in which the resistivity of a dielectric film is relatively low. On the other hand, a thickness of 500 μm is required with respect to a voltage of ±3 KV that is used in Coulomb type in which the resistivity is high. Therefore, the thickness of the insulating layer is normally 200 to 500 μm, and is set to 350 μm in this embodiment.

Next, tungsten is thermal-sprayed to form two electrostatic chuck electrodes, that is, the inner electrostatic chuck electrode 24 and outer electrostatic chuck electrode 25, in a manner that the electrodes take the shape of concentric rings. Then, surfaces of the formed electrodes are polished to adjust the thicknesses thereof. Smaller thicknesses of the electrostatic chuck electrodes advantageously prevent the thermal characteristic thereof from deteriorating. The distance between the inner and outer electrostatic chuck electrodes is, for example, 2 mm. As this distance is shorter, an area on which absorptive power has an effect is advantageously secured in a large scale. However, the distance is typically set to 2 to 3 mm in terms of the withstand voltage between the two electrodes.

Also in terms of the manufacturing stability, it is sufficient that the thicknesses of the thermal-sprayed films are 40 to 100 μm, since the thermal-sprayed films only undergo application of a voltage and, further, the grain boundary diameter of the thermal-sprayed films is 20 to 50 μm. The thicknesses of the thermal-sprayed films are set to 50 μm in this embodiment.

Independent voltages may be applied to the electrostatic chuck electrodes, that is, the electrostatic chuck acts as a bipolar electrostatic chuck. In this embodiment, a positive voltage is applied to the inner electrode, and a negative voltage is applied to the outer electrode. Even if the polarities are reverse, it will be no problem, since the electrodes are electrically coupled to the electric plug buried in the through hole.

Finally, high-resistance alumina is thermal-sprayed to form a dielectric film 28 that will act as an absorption film of the electrostatic chuck. Then, a surface of the formed dielectric film is polished to adjust the thickness thereof. The thickness of this absorption film depends on the amplitude of absorptive power that must be secured and a withstand voltage with respect to a voltage that must be applied to cause the absorptive power. Also, the absorption film must have a thickness such that clamping force, by which even a wafer having warpage due to a film made thereon is stably absorbed, is generated.

According to an experiment conducted by the inventors, the electrostatic chuck requires clamping force of at least 10 kPa or higher. In order to stably generate such absorptive power at the above-described application voltage, the thickness of the absorption film must be 150 to 250 μm for Coulomb type and 250 to 500 μm for Johnsen-Rahbek type. For this reason, the thickness of the absorption film is set to 200 μm in this embodiment.

A method for feeding the heaters, which is a feature of this embodiment, will now be described with reference to FIG. 1. The high-frequency power supply 10 is intended to apply a bias voltage to the wafer and is coupled to the base material 2 of the electrostatic chuck via the cable 21. The bias frequency of the high-frequency power supply 10 is selected from the range of, for example, 400 KHz to 13.56 MHz as appropriate. A direct-current power supply 11 for applying a direct-current to the electrostatic chuck electrodes is coupled to the electrodes via the filter 27 and coaxial cables 36 and 37. While the direct-current power supply is coupled to only the inner electrode in FIG. 1, it is also coupled to the outer electrode in a similar configuration, as a matter of course, in a bipolar electrostatic chuck as shown in this embodiment.

Next, a reference numeral 38 represents a heater power supply for supplying power to the outer heater 22. The heater power supply may be any of a direct-current power supply or an alternating current power supply of the order of 50 to 60 Hz. While only one feeding part of the outer heater is coupled to the heater power supply in FIG. 1, off course, the outer heater has another feeding part coupled to the heater power supply. Also, the heater power supply is coupled to the inner heater with a similar configuration. Here, the heater power supply is coupled to the filter 17 via the coaxial cable 29 whose both ends serve as BNC female connectors. In other words, an output terminal of the heater power supply and a connection terminal of the filter 17 serve as BNC male connectors. The filter 17 and the heater feeding part of the electrostatic chuck are coupled via the coaxial cable 40 whose both ends serve as BNC female connectors. In other words, a connection terminal of the filter and a connection terminal of the heater feeding part serve as BNC male connectors.

The main components of the filter are a coil and a capacitor. The coil is intended to prevent application of a bias voltage applied to the base material and a high-frequency voltage for plasma generation, to the heater power supply. The capacitor serves to ground components that have not been eliminated, among the above-described high-frequency components. Thus, the filter according to this embodiment acts as a low-path filter. This low-path filter has a function of providing a power component of, for example, less than 400 KHz and direct-current power to the heaters.

By feeding the heaters during plasma processing in such a configuration, no high-frequency voltage flows into the heater power supply. This allows the heaters to operate without malfunctioning due to noise or being broken. As a result, the temperature of a wafer undergoing plasma processing is controlled with good reproducibility and high reliability.

A configuration for suppressing a damage caused by the heaters and an advantage thereof, which are another feature of the present invention, will now be described. Note that electromagnetic waves provided/applied into the vacuum processing chamber to generate plasma, that is, high-frequency power for plasma generation, such as microwaves, UHF, and RF, can also cause a damage. For this reason, use of a low-path filter as the filter 17 must prevent application of microwaves or high-frequency waves for plasma generation and power having a high frequency higher than a high-frequency voltage applied to the electrostatic chuck by the bias power supply, to the heater power supply. While the filter 17 is not limited to a low-path filter, it must have a function of performing filtering so as to prevent application of microwaves and high-frequency waves for plasma generation and power having a high frequency in a predetermined frequency range including a high-frequency voltage applied to the electrostatic chuck by the bias power supply, to the heater power supply.

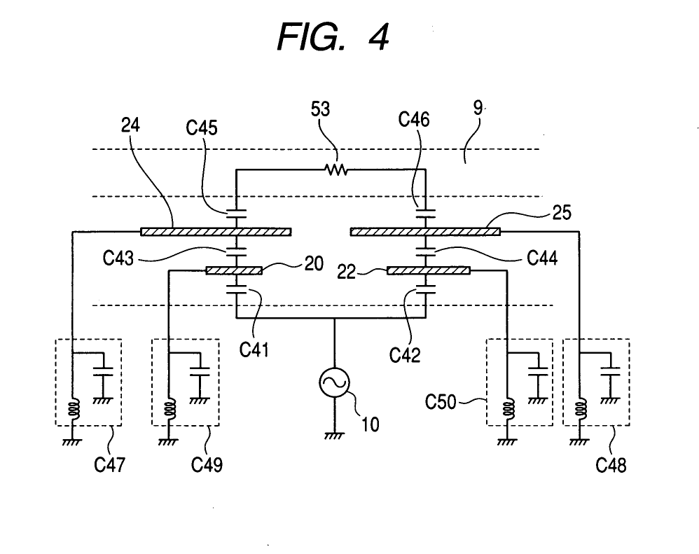

To plainly describe the features of the present invention, an equivalent circuit model of FIG. 4 will be used in which the basic concept of the present invention, that is, the occurrence mechanism of a damage that can be caused by the heater-built-in electrostatic chuck, which the inventors newly found, is simplified. While the equivalent circuit model is actually more complicated, only main elements are shown in the circuit model for the sake of clarity.

In order to simplify the description, only the high-frequency power supply 10 for a bias is shown in the diagram. However, high-frequency power for plasma generation need not be separated from the high-frequency power supply 10 for a bias if it is high-frequency power to be applied to the base material on which the heater-built-in electrostatic chuck is laminated, as a matter of course.

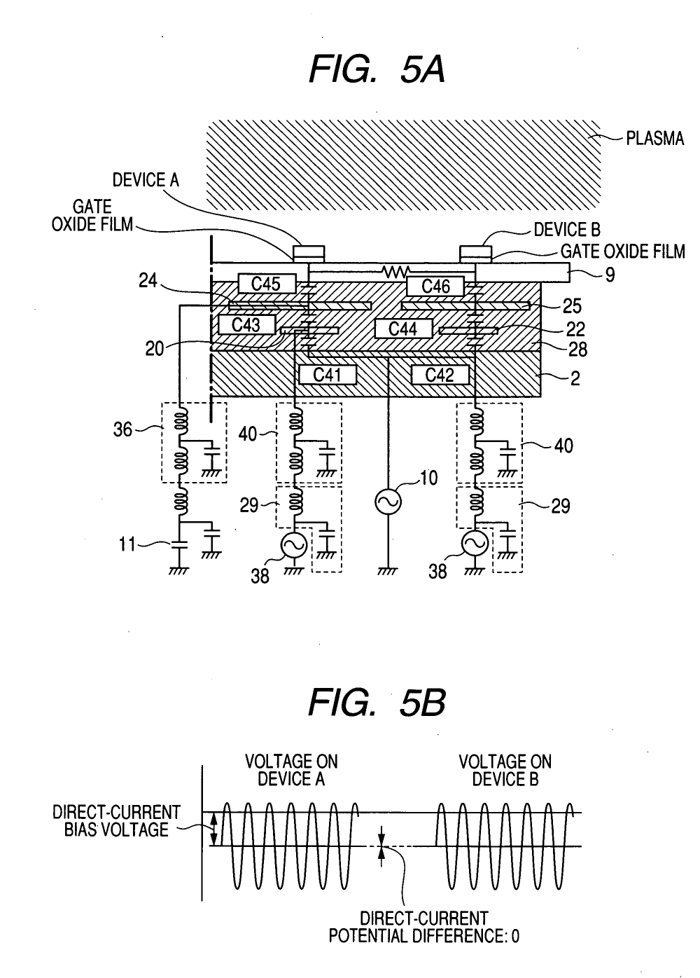

FIG. 5A shows an equivalent circuit model including the heater-built-in electrostatic chuck mechanism according to this embodiment during etching. FIG. 5B shows states of respective high-frequency voltages applied to the devices A and B during etching.

In FIGS. 4 and 5A, reference numerals C41 and C42 denote a capacitance between the inner heater and the base material and a capacitance between the outer heater and base material, respectively. Reference numerals C43 and C44 denote a capacitance between the inner heater and inner electrostatic chuck electrode and a capacitance between the outer heater and outer electrostatic chuck electrode, respectively. Reference numerals C45 and C46 denote a capacitance on the inner electrostatic chuck electrode and a capacitance on the outer electrostatic chuck electrode, respectively. Reference numerals C47 to C50 denote equivalent circuits from the inner electrostatic chuck electrode, outer electrostatic chuck electrode, inner heater, outer heater, and power supply. These equivalent circuits each include a coaxial cable and a filter, and each mainly represented by the capacitance of the coaxial cable and a coil of the filter circuit. The circuits for applying a voltage to the electrostatic chuck electrode have substantially identical configurations. The same goes for the circuits for applying a voltage to the heater.

Among these, the respective capacitances on the two electrostatic chuck electrodes are preferably identical in terms of such as preventing remaining absorptive power of the bipolar electrostatic chuck. In this embodiment, the two electrostatic chuck electrodes have approximately identical areas. Accordingly, the capacitances C45 and C46 are approximately identical.

In the first embodiment, the filter prevents a high-frequency voltage from leaking via the heater power supply. Also, in order to make the leakage from the feeding cable of the inner heater to a ground and the leakage from the feeding cable of the outer heater to a ground approximately identical so as to make the potential difference on the surface of the wafer approximately zero, the respective areas of the inner and outer heaters are made-approximately identical so that the capacitances C41 and C42 in FIG. 4 are approximately identical. Further, the coaxial cables having identical capacitances per unit length and having approximately identical lengths are used so that the respective capacitances of the coaxial cables are approximately identical.

As shown in FIG. 5B, the direct-current potential difference between the respective high-frequency voltages applied to the devices A and B during etching is zero. Specifically, in this embodiment, the respective capacitances between the heaters and the base material are identical and the respective capacitances between the heaters and the electrostatic chuck internal electrodes disposed the heaters are also identical; therefore, no difference is made between the respective high-frequency voltages applied to the devices A and B. As a result, no leak current passes through the gate oxide film, thereby causing no damage to the elements.

According to the plasma processing apparatus including a heater-built-in electrostatic chuck having such a configuration, the heaters are fed without making a potential difference in the plane of the wafer during plasma processing. Thus, plasma processing is performed while adjusting the temperature distribution with good responsiveness without causing damage due to the heaters. As a result, a plasma processing apparatus is provided that allows reductions in manufacturing cost of semiconductor devices as well as has high productivity.

This embodiment has been described using the two concentric ring-shaped electrostatic chuck electrodes as an example. However, the present invention is also applicable to a heater-built-in bipolar electrostatic chucks in which heaters are disposed below other flat electrostatic chuck electrodes such as a pair of approximately semicircular electrostatic chuck electrodes or a pair of comb-teeth-shaped electrostatic chuck electrodes (the same goes for the following bipolar electrostatic chuck embodiments).

### Second Embodiment

In the first embodiment, the two heaters having approximately identical areas are disposed below the two chuck electrodes having approximately identical areas so that the heaters are completely hidden behind the chuck electrodes.

However, the number of heaters for controlling the wafer temperature is not limited to two. According to the technical idea of the present invention, even if one heater is buried around the periphery (or inner circumference) of the electrostatic chuck, for example, in order to fine-tune the temperature of a wafer only around the periphery thereof, no damage occurs. In this case, it is sufficient to dispose a dummy-heater that has an area approximately identical to that of the outer heater disposed around the periphery and is not coupled to the heater power supply, in a layer lower the inner electrostatic chuck electrode, and to couple a coaxial cable having a length L approximately identical to that of a cable coupled to the outer heater, to this dummy-heater. By using a bipolar electrostatic chuck including one heater having such a configuration, a wafer is temperature-controlled without causing damage, as with the above-described bipolar electrostatic chuck including two heaters.

### Third Embodiment

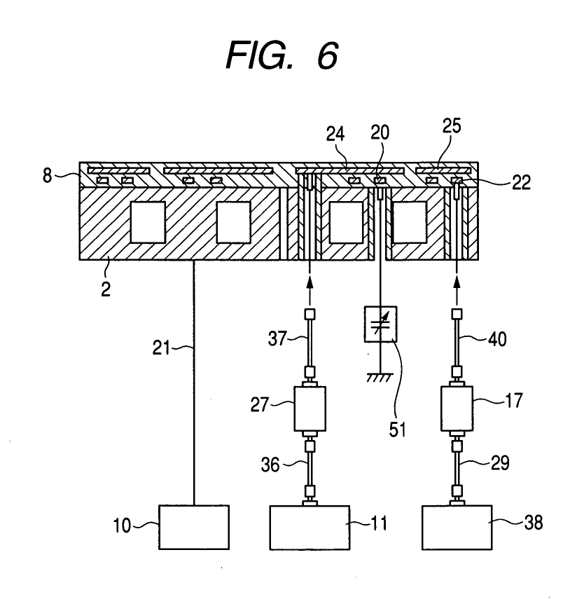

FIG. 6 shows a third embodiment of the present invention. In this embodiment, the inner heater according to the first embodiment includes a ground circuit for coupling a variable capacitor 51 to a ground via the inner heater, in addition to the circuit including the coaxial cable and filter coupled to the heater power supply. By adjusting the capacitance of the variable capacitor 51, the capacitance from the inner heater to a ground is made identical to that from the outer heater to a ground. Thus, the high-frequency voltage on the inner electrostatic chuck electrode and that on the outer electrostatic chuck electrode are made approximately identical. As a result, the potential difference on the wafer is made approximately zero. This is an effective solution in a case where the inner and outer heaters have different areas and thus the capacitances C41 and C42 are different.

According to this embodiment, the potential difference on a wafer made in a case where plasma is distributed around the center of a wafer as well as around the periphery thereof is also corrected by adjusting the variable capacitor.

Thus, the plasma processing apparatus including a heater-built-in electrostatic chuck according to this embodiment prevents a damage caused by the heaters, as well as performs plasma processing while controlling the temperature of a wafer.

While the variable capacitor is coupled only to the inner heater in this embodiment, it may be coupled to each of the two heaters. Also, while the electrostatic chuck includes the two separate heaters in this embodiment, the number of included heaters is not limited to two. Even if the electrostatic chuck includes three or more heaters, the potential difference is adjusted as well.

### Fourth Embodiment

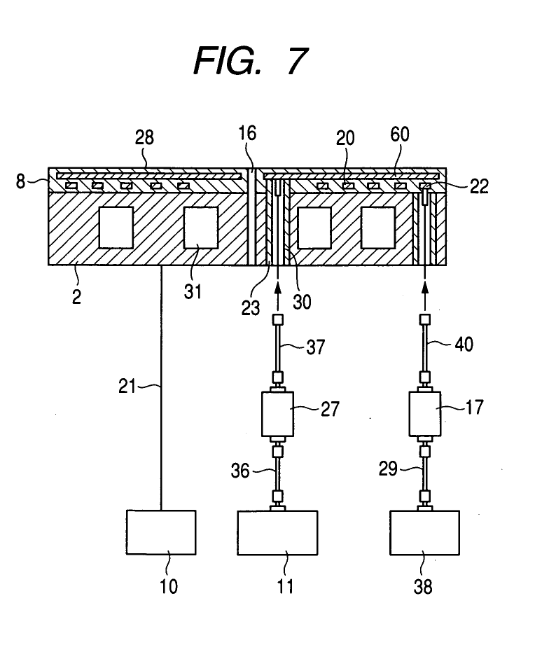

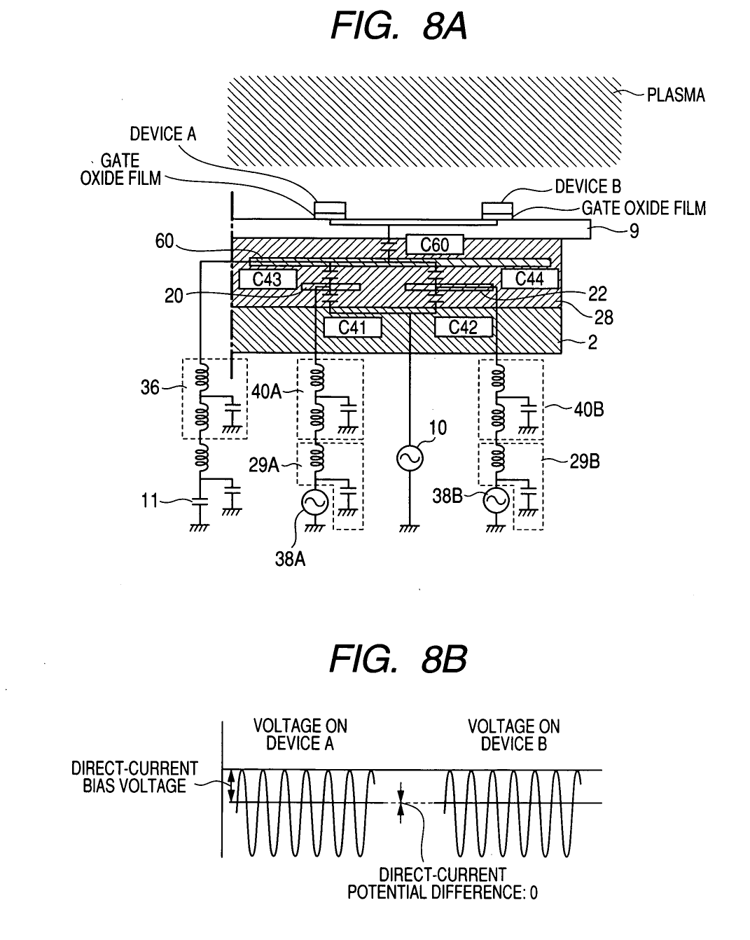

A unipolar electrostatic chuck according to a fourth embodiment of the present invention will now be described with reference to FIGS. 7 and 8A and 8B. As described above, in order to prevent a damage, it is sufficient to make an equivalent electric circuit from the base material to the device A and that from the base material to the device B identical to each other, or to make them similar to each other to the extent that no damage is caused.

To realize this, in this embodiment, heaters are disposed below an internal electrode 60 of a unipolar electrostatic chuck so that the heaters are completely hidden behind the internal electrode when seen from a wafer, as shown in FIG. 7. Thus, the potentials are made uniform by the conductive internal electrode 60. As a result, no potential difference is made between the devices A and B on the wafer, thereby preventing damage.

By disposing the two heaters 20 and 22 below the internal electrode 60 of the unipolar electrostatic chuck so that the heaters are completely hidden behind the internal electrode when seen from the wafer, potentials in the plane of the wafer are identical even if the respective capacitances between the heaters 20 and 22 and base material are different and the respective capacitances between the heaters 20 and 22 and electrostatic chuck internal electrode are different. This is because the electrostatic chuck internal electrode is made of a conductive material as shown in FIG. 8A. That is, in this embodiment, the capacitance C60 on the electrostatic chuck internal electrode is identical in the plane; therefore, no difference is made between the respective high-frequency voltages applied to the devices A and B. As a result, as shown in FIG. 8B, the direct-current potential difference between the respective high-frequency voltages applied to the devices A and B during etching is made zero.

Thus, no difference is made between the high-frequency voltages applied to the devices A and B. As a result, no leak current passes through the gate oxide film, thereby causing no damage to the devices.

### Fifth Embodiment

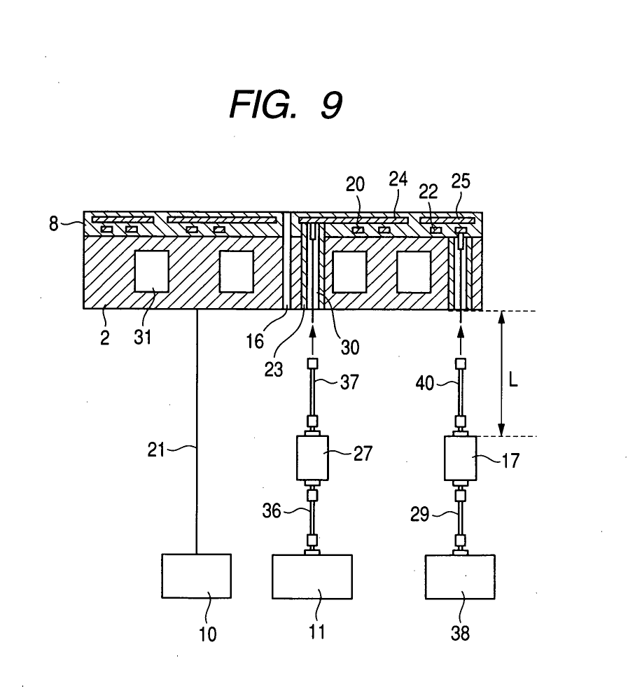

A fifth embodiment of the present invention will now be described with reference to FIG. 9 to 16. In this embodiment, as shown in FIG. 9, a part of the heater is seen through a clearance between the electrostatic chuck electrodes, unlike in the first embodiment. A case in which the inner and outer heaters have different areas and a case in which the number of heaters is different from that in the first embodiment are also considered.

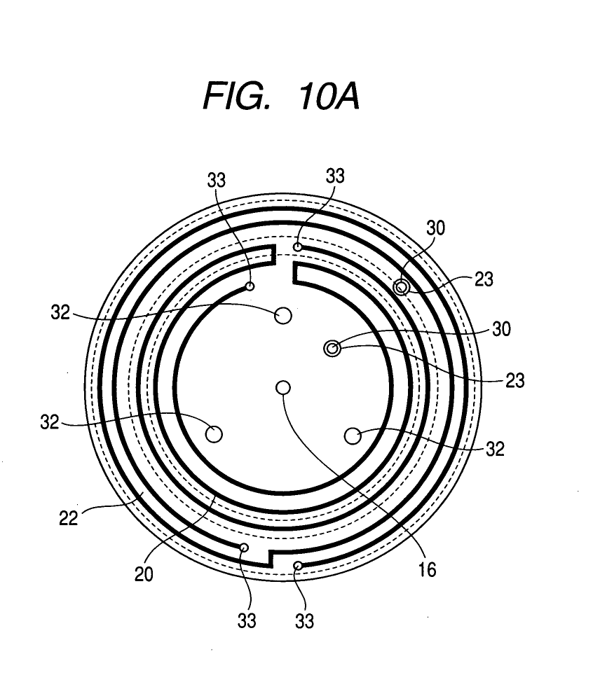

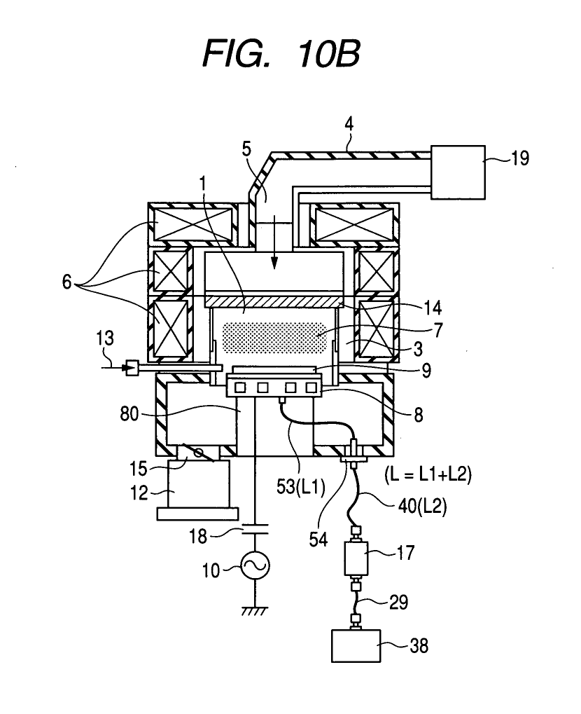

FIG. 10A shows a heater pattern of the fifth embodiment. The inner heater 20 is disposed in a bipolar electrostatic chuck so that a part of the inner heater is seen through an annular clearance between the electrostatic chuck electrodes 24 and 25. The distance between the inner and outer electrostatic chuck electrodes is set to, for example, 2 mm.

FIG. 10B is a schematic sectional view of an effective magnetic field microwave plasma processing apparatus according to this embodiment.

Also in this embodiment, the electrostatic chuck includes heaters (inner heater 20 and outer heater 22), which are fed by the heater power supply 38. The heater power supply 38 is coupled to the BNC type current introduction terminal 54 attached to the vacuum chamber, via the filter 17 for preventing application of a high-frequency voltage of 400 KHz applied to the electrostatic chuck by the microwave and the bias power supply, to the heater power supply and via the coaxial cable 29 and coaxial cable 40 (length: L2). The back of the electrostatic chuck 8 and a portion of the current introduction terminal 54 inside the vacuum chamber are coupled via the coaxial cable 53 (length: L1). The sum (L=L1+L2) of the length of the coaxial cable 53 and that of the coaxial cable 40 is set to 5 m. This cable length L, that is, a cable length L from the low-path filter 17 outside the vacuum chamber to the back of the electrostatic chuck inside the vacuum chamber must be properly managed, since it affects whether or not the devices are damaged, as will be described later.

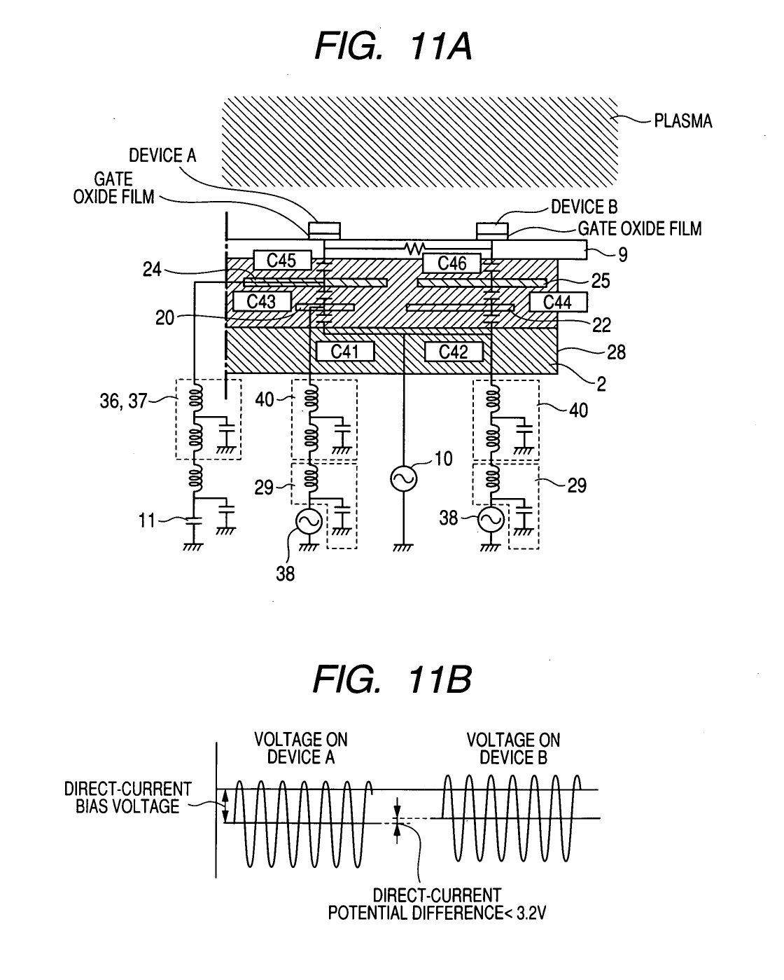

As shown in FIG. 11B, according to this embodiment, by determining the heater feeding cable length L from the low-path filter to the electrostatic chuck according to the bias frequency, the potential difference is suppressed to a level such that no damage is substantially caused, without using the variable capacitor according to third embodiment.

As described with reference to FIG. 17, if plural heaters buried in a layer lower than two internal electrodes have difference configurations, a direct-current potential difference is made between the respective high-frequency voltages applied to the devices A and B. This may cause damage to the devices. Specifically, a damage may be caused in the following cases: (1) in a bipolar electrostatic chuck, one of two heaters buried in a layer lower than two internal electrodes is seen through a clearance between the two chuck electrodes; (2) even if not seen as described above, the two heaters disposed below the two chuck electrodes have different areas; and (3) in a bipolar electrostatic chuck, three or more heaters, that is, the number of heaters different from that of the electrostatic chucks are disposed.

This embodiment provides a configuration that prevents damage in these cases.

As described above, “Charging Damage in a Semiconductor Process,” Realize Science & Engineering Center Co., Ltd., pp. 297 discloses that if a gate oxide film is affected by an electric field with intensity of 8M V/cm or higher, a leakage current is rapidly increased, whereby the gate oxide film is broken down. In recent devices packed with increased density, the thickness of a gate oxide film has been reduced down to 10 nm or lower. Occurrence of a direct-current potential difference as described above in the plane of a wafer causes breakdown of the gate oxide film, thereby causing a damage to the elements and thus causing reductions in yield. For example, if the thickness of a gate insulating film is 4 nm and the electric strength is 8MV/cm, the allowable value of a potential difference made on a wafer is conceivably on the order of 3.2 V. Therefore, in order to prevent the elements from being damaged after plasma processing, the direct-current potential difference on the wafer must be managed so that it falls within is 3.2 V. However, even if the thickness of the gate oxide film is reduced, this potential difference requirement is not always made more stringent. It is said that if the thickness of the gate oxide film is further reduced down to, for example, 4 nm or less, electrical stress applied to the gate insulating film is reduced, since application of a voltage to the gate insulating film cause a flow of a tunnel current. For this reason, the allowable value of a potential difference on a wafer being processed is conceivably on the order of 3.2 V.

As is apparent from FIG. 11A, the potential on an element above a clearance between the two electrostatic chuck electrodes as well as the potentials on the devices A and B disposed above the two electrodes may become a problem-in the circuit. However, if the distance between the inner and outer electrostatic chuck electrodes is on the order of 2 mm as shown in this embodiment, such a potential has conceivably little influence, since the area above the clearance is sufficiently smaller than the areas above the absorption electrodes

It is obvious that a cable having a smaller capacitance is advantageous as a coaxial cable to be used as the heater feeding cable in terms of suppressing power leaking from the heaters as much as possible. However, it is appropriate to use a commercially available standard product in terms of the manufacturing cost. Taking into account power to be supplied to the heaters, it is best to use a coaxial cable on the order of 100 pF/m per length. As for the inductance of the filter, a filter having a larger inductance is advantageous in that larger impedance is obtained. However, from a calculation result to be described later, it is found that if the filter has an inductance of 1 mH or more, the effect of the filter is sufficiently obtained. For this reason, the inductance is set to 5 mH in this embodiment. Note that in order to reduce the size of the coil as much as possible, a copper wire is wound-around the ferrite core. As a typical size, a coil is wound around a ferrite substrate of 100 mm □ and the thickness is suppressed down to approximately 40 mm.

As the difference between the capacitances C41 and C42 shown in FIG. 4 is increased, the potential difference made on the surface of the wafer is increased. These capacitances vary with the distance between the base material and heater, the distance between the heater and electrostatic chuck electrode, and the area of the heater. However, if heaters are disposed in a concentric manner as shown in FIG. 10A, the heater width is changed from 2 mm to 3 mm, and the heater-to-heater interval is changed from 2 mm to 3 mm, the areas of these heaters disposed below the electrostatic chuck electrodes are changed from approximately 30% to approximately 70% of the areas of the electrodes for an electrostatic chuck with a diameter of 300 mm. Therefore, it is understood that by setting a capacitance such that the potential difference on the wafer surface is 3.2 V or less even in a combination that most significantly deteriorates the potential on the surface of the wafer, among combinations of the thicknesses of the films described in the first embodiment, damage is prevented.

Then, using this combination, the respective potential differences made on the wafer at bias frequencies of 400 KHz, 800 KHz, 2 MHz, and 13.56 MHz used in the plasma etching apparatus were estimated from calculations. If the potential difference made on the wafer is obtained, to what % of Vₚₚ the direct-current components generated on the wafer correspond is important. Usually, it is appropriate to think that the direct-current components correspond to ½ of Vₚₚ at the maximum. While the maximum value of Vₚₚ varies with the plasma conditions, it is naturally determined by considering the withstand voltage of the dielectric film. It is typically 2 kV. Therefore, the largest direct-current component generated on the wafer is −1 KV. Under this condition, the difference between direct-current potentials above the inner and outer electrostatic electrodes is estimated from a calculation.

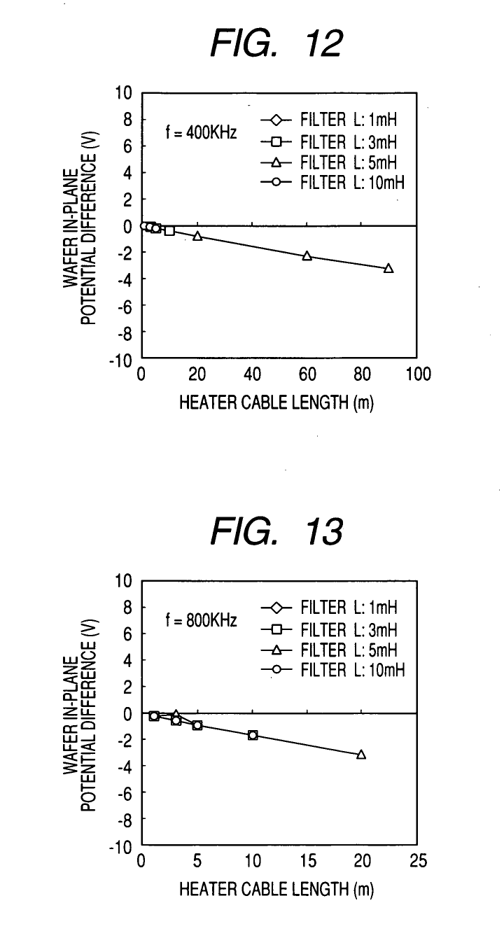

FIG. 12 shows a relation between the coaxial cable length L from the filter to the heater and the direct-current potential difference on the wafer in a case where the bias frequency is 400 KHz. In the graph, the respective states when the inductance of the filter is 1 mH, 3 mH, 5 mH, and 10 mH are shown (same in the examples below). From this graph, it is understood that if the bias frequency is 400 KHz and the coaxial cable length L is 90 m or less, the potential difference is suppressed down to 3.2 V or less regardless of the amplitude of the inductance of the filter.

On the other hand, as described above, the coaxial cable length L includes the length (L1) of the coaxial cable between the back of the electrostatic chuck and a portion of the current introduction terminal inside the vacuum chamber. The coaxial cable length L1 inside the vacuum chamber is typically within 1 m, for example, on the order of 50 to 80 cm. Also, the filter is provided outside the vacuum chamber. In other words, the lower limit of the coaxial cable length L is the addition of the cable length until the filter outside the vacuum chamber to the coaxial cable length L1 inside the vacuum chamber. It is on the order of 1 m.

FIG. 13 shows a relation between the cable length L from the filter to the heater and the direct-current potential difference on the wafer in a case where the bias frequency is 800 KHz. From this graph, it is understood that if the bias frequency is 800 KHz and the coaxial cable length L is 20 m or less, the potential difference is suppressed down to 3.2 V or less. The lower limit of the coaxial cable length L is the addition of the cable length until the filter outside the vacuum chamber to the coaxial cable length L1 inside the vacuum chamber. It is on the order of 1 m.

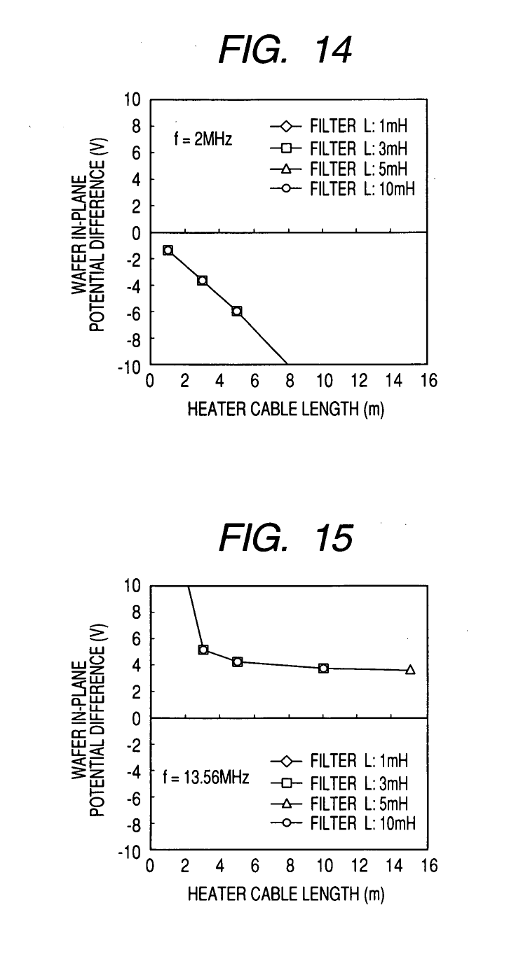

FIG. 14 shows a relation between the cable length L from the filter to the heater and the direct-current potential difference on the wafer in a case where the bias frequency is 2 MHz. From this graph, it is understood that if the bias frequency is 2 MHz and the coaxial cable length L is 3 m or less, the potential difference is suppressed down to 3.2 V or less. The lower limit of the coaxial cable length L is the addition of the cable length until the filter outside the vacuum chamber to the coaxial cable length L1 inside the vacuum chamber. It is on the order of 1 m.

FIG. 15 shows a relation between the cable length L from the filter to the heater and the direct-current potential difference on the wafer in a case where the bias frequency is 13.56 MHz. From this graph, it is understood that if the bias frequency is 13.56 MHz and the coaxial cable length L is 10 m or more unlike in the above examples, the potential difference is suppressed down to 3.2 V or less. However, even if the cable length L is increased too much, no large difference is made in advantage. Therefore, the upper limit of the coaxial cable length L is a length of more than 10 m that is in the optimum range in relation to the inductance of the filter, specifically, a dozen or so m.

The above-described estimations are those under the conditions in which a potential difference is most likely to be made on the wafer in a heater-built-in electrostatic chuck according to this embodiment. Conversely, it is considered that, by setting the coaxial cable length L according to each bias frequency, a potential difference that is likely to cause damage is not made in any case. While the feeding cables of the electrostatic chuck electrodes also affect the potential on the wafer, any change in length L of the heater cable does not affects the potential on the wafer if the feeding cables are coupled to the electrostatic chuck electrodes having identical areas.

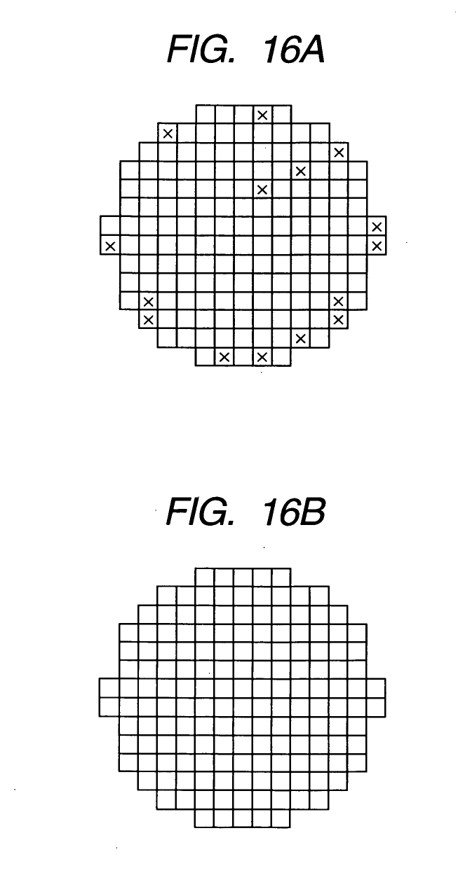

FIGS. 16A and 16B are intended to compare a damage occurrence map (FIG. 16A) obtained when a wafer is processed at a frequency of 400 KHz and the potential difference of more than 3.2 V in the plane of the wafer and a damage occurrence map (FIG. 16B) obtained when the wafer is processed while suppressing the potential difference in the plane of the wafer down to 3.2 V or less using the cable length according to this embodiment.

From these maps, it is understood that no damage is caused when the wafer is etched using the cable meeting the conditions according to this embodiment.

As described above, in the plasma processing apparatus in which each heater and the filter is coupled via the coaxial cable whose length is set to the proper length L according to each bias frequency, each heater is fed without making a potential difference on the plane of the wafer during plasma processing, even if the inner heater in the bipolar electrostatic chuck is disposed so that a part of the inner heater is seen through the annular clearance between the pair of electrostatic chuck electrodes.

Thus, plasma processing is performed while adjusting the temperature distribution with good responsiveness so that no damage is caused by the heaters in the electrostatic chuck. As a result, a plasma processing apparatus is provided that allows reductions in manufacturing cost of semiconductor devices as well as has high productivity.

This embodiment employs a high-resistance film, whose resistivity is 1×1015 Ωcm or more, as a dielectric film and a type that generates so-called-Coulomb force as clamping force. However, this embodiment is not limited thereto. A so-called “Johnsen-Rahbek” type electrostatic chuck that generates clamping force with resistivity of the order of 1×109 to 1012 Ωcm may be employed. While the insulating layer and dielectric film are mainly made of alumina, they are not limited thereto. They may be made of, for example, yttria, silicon carbide, aluminum nitride, or the like.

While this embodiment uses titanium as the base material, the base material is not limited thereto. Other metals such as aluminum, aluminum alloy, and stainless alloy may be used. While the electrostatic chuck is formed by thermal-spraying in this embodiment, the method for forming the electrostatic chuck is not limited thereto. A plate-shaped member that has approximately a similar configuration and in which a heater and an electrostatic chuck electrode are formed by sintering may be attached to the base material according to this embodiment using an adhesive. In this case, it is difficult to form a sintered compact ceramics as thin as the multilayer films according to this embodiment; therefore, the thickness is increased as a whole. However, the way that heat of the heater is conducted and the way that the clamping force of the electrostatic chuck is generated are similar to those in this embodiment except that a portion corresponding to an insulating layer in the lowest layer of the electrostatic chuck according to this embodiment is thicker. Therefore, the technical idea of this embodiment is also applicable to an electrostatic chuck formed in such a way.

While the number of built-in heaters is two in this embodiment, it is not limited thereto. It may be one or three or more. The number of built-in heaters is preferably selected as appropriate according to a temperature distribution or temperature responsiveness that must be realized. Also, the number of turns of each heater and the pattern of each heater are not always limited to those in this embodiment and is preferably determined as appropriate according to a temperature distribution or temperature responsiveness that must be realized.

What is claimed is:

1. A plasma processing apparatus comprising:
a sample stage provided in a processing chamber for holding a sample;
a plasma generating unit for generating plasma in the processing chamber;
an electrostatic chuck electrode and a heater both disposed on the sample stage, wherein the heater coupled to a heater power supply via a current-carrying path;
a bias power supply coupled to the sample stage for controlling ion energy;
an exhaust device for decompressing the processing chamber; and
a power restraint unit for restraining high-frequency power from flowing into the current-carrying path of the heater.

2. The plasma processing apparatus according to claim 1,
wherein the power restraint unit includes a low-path filter that prevents a flow of power having a frequency equal to or higher than a frequency of high-frequency power from the bias power or the plasma generating unit, into the current-carrying path.

3. The plasma processing apparatus according to claim 1,
wherein the power restraint unit includes a filter that filters a current having a frequency in a predetermined range including a frequency of high-frequency power from the bias power or the plasma generating unit.

4. A plasma processing apparatus comprising:
a sample stage provided in a processing chamber for holding a sample;
a plasma generating unit for generating plasma in the processing chamber;
a heater-built-in electrostatic chuck disposed on the sample stage;
a bias power supply coupled to the sample stage and intended to control ion energy; and
an exhaust device for decompressing the processing chamber,
wherein the heater-built-in electrostatic chuck includes a heater, an electrostatic chuck electrode, and a dielectric film laminated on a conductive base material, and
the heater is disposed below the electrostatic chuck electrode in a manner that the heater is completely hidden behind the electrostatic chuck electrode.

5. The plasma processing apparatus according to claim 4,
wherein the heater-built-in electrostatic chuck includes:
at least two heaters laminated on a conductive base material to which a high-frequency bias voltage is to be applied;
a pair of electrostatic chuck electrodes having substantially identical areas; and
a dielectric film, and
wherein the at least two heaters are disposed below the electrostatic chuck electrodes in a manner that the heaters are completely hidden behind the electrostatic chuck electrodes.

6. The plasma processing apparatus according to claim 5,
wherein at least one of the plurality of heaters is coupled to ground via a variable capacitor.

7. A plasma processing apparatus comprising:
a sample stage provided in a processing chamber and intended to hold a sample;
a plasma generating unit for generating plasma in the processing chamber;
a heater-built-in electrostatic chuck disposed on the sample stage; and
an exhaust device for decompressing the processing chamber,
wherein the heater-built-in electrostatic chuck includes:
at least two heaters and a pair of electrostatic chuck electrodes, the heaters and the electrostatic chuck electrodes laminated on a conductive base material to which a high-frequency bias voltage is to be applied,
the heaters are coupled to a heater power supply via a low-path filter for preventing a flow of high-frequency power into a current-carrying path of the heaters and via a coaxial cable, and
a length of the coaxial cable for coupling a back of the electrostatic chuck on the sample stage with the filter is set in a predetermined range.

8. The plasma processing apparatus according to claim 7,
wherein if a frequency of the bias power supply is approximately 400 KHz or 800 KHz, the low-path filter and the heater are coupled via the coaxial cable having a length of 15 m or less as a length equal to or less than the predetermined value and having a capacitance of 100 pF/m or less.

9. The plasma processing apparatus according to claim 7,
wherein if a frequency of the bias power supply is approximately 2 mHz, the low-path filter and the heater are coupled via the coaxial cable having a length of 3 m or less as a length equal to or less than the predetermined value and having a capacitance of 100 pF/m or less.

10. The plasma processing apparatus according to claim 7,
wherein if a frequency of the bias power supply is approximately 13.56 MHz, the low-path filter and the heater are coupled via the coaxial cable having a length of 10 m or more as a length equal to or less than the predetermined value and having a capacitance of 100 pF/m or less.
